(19) United States
(12) Patent Application Publication
(10) Pub. No.: US 2007/0034940 A1
(43) Pub. Date: Feb. 15, 2007

(54) MOS semiconductor device

(75) Inventor: Tomoya Sanuki, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/501,917

(22) Filed: Aug. 10, 2006

(30) Foreign Application Priority Data
Aug. 12, 2005 (JP) 2005-234718

(51) Int. Cl. H01L 29/76; H01L 29/94; H01L 31/00

(52) U.S. Cl. 257/327

(57) ABSTRACT

A semiconductor device comprises a gate electrode provided on a gate insulating film, a side wall insulating film provided on a side wall of the gate electrode through a protection insulating film, a barrier SiN film provided to cover the gate electrode and the side wall insulating film, an inter-level insulating film provided to cover the barrier SiN film, and an SOG-series high-stress material being used as part of the inter-level insulating film.

### CROSS-REFERENCE TO RELATED APPLICATIONS

This application is based upon and claims the benefit of priority from prior Japanese Patent Application No. 2005-234718, filed Aug. 12, 2005, the entire contents of which are incorporated herein by reference.

### BACKGROUND OF THE INVENTION

1. Field of the Invention

This invention relates to a MOS semiconductor device and more particularly to a MOS semiconductor device in which stress from a barrier silicon nitride film (SiN film) can be changed.

2. Description of the Related Art

In developing a semiconductor device, it is an important subject to enhance the performance of a CMOS device while the transistor size thereof is shrinked. Generally, an SiN-series film is formed on a MOS transistor and the SiN film (barrier SiN film) is necessary to perform a process of forming a contact structure for source and drain regions of the MOS transistor.

The barrier SiN film generally has stresses, and both of the stresses of tensile stress and compressive stress can be applied to the MOS transistor formed under the film by adequately selecting the process of forming the SiN film.

In this case, the performance can be enhanced by applying tensile stress to an N-type MOS transistor from the barrier SiN film, and the performance can be enhanced by applying compressive stress to a P-type MOS transistor from the barrier SiN film. If the opposite stresses are applied, the performance such as on-current of the N-type and P-type MOS transistors will be degraded.

For example, if each gate structure of CMOS transistors having a side wall insulating film of the SiN film formed on the side wall is covered with the barrier SiN film, the compressive stress is applied to both of the N-type and P-type MOS transistors. As a result, as described previously, the performance of the P-type MOS transistor is enhanced, but that of the N-type MOS transistor is degraded.

That is, for improving each performance of the N-type and P-type MOS transistors by the stress having opposite directions from the barrier SiN film, it is difficult to enhance the performance both of the N-type and P-type MOS transistors in process. Further, if different barrier SiN films are used in the N-type region and P-type region, the processes will be increased.

In order to eliminate the above problem, there have been proposed some structures such that the performance of the N-type MOS transistor is more enhanced and that of the P-type MOS transistor is not almost degraded and that a barrier SiN film structure having stresses of different directions in the N-type and P-type MOS transistors.

In either case, it is difficult to change the stress from the structure other than the barrier SiN film of the MOS transistor and the stress from the barrier SiN film, whereby the performance of the MOS transistors can not be enhanced.

### BRIEF SUMMARY OF THE INVENTION

According to a first aspect of the present invention, a semiconductor device comprises a gate electrode provided on a gate insulating film, a side wall insulating film provided on a side wall of the gate electrode through a protection insulating film, a barrier SiN film provided to cover the gate electrode and the side wall insulating film, an inter-level insulating film provided to cover the barrier SiV film, and an SOG-series high-stress material being used as part of an inter-level insulating film.

According to a second aspect of the present invention, a MOS semiconductor device comprises a gate electrode provided on a gate insulating film, a side wall insulating film directly provided on a side wall of the gate electrode, and a barrier SiN film provided to cover the gate electrode and the side wall insulating film, wherein a material whose volume is contractible is used as the side wall insulating film.

According to a third aspect of the present invention, a gate structure of a MOS semiconductor device comprises a semiconductor substrate, and N-type and P-type MOS transistors provided in the semiconductor substrate and isolated by STI, each of the N-type and P-type MOS transistors comprises a gate electrode provided on a gate insulating film, a side wall insulating film provided on a side wall of the gate electrode through a protection insulating film, a barrier SiN film provided to cover the gate electrode and the side wall insulating film, and an inter-level insulating film provided to cover the barrier SiN film, an SOG-series high-stress material being used as part of the inter-level insulating film in the N-type MOS transistor.

### BRIEF DESCRIPTION OF THE DRAWINGS

FIG. 1 is a cross sectional view schematically showing a gate structure of a CMOS semiconductor device according to a first embodiment.

FIG. 2 is a cross sectional view schematically showing a gate structure of a CMOS semiconductor device according to a second embodiment.

FIG. 3 is a cross sectional view schematically showing a gate structure of a CMOS semiconductor device according to a third embodiment.

FIG. 4 is a cross sectional view schematically showing a gate structure of a CMOS semiconductor device according to a fourth embodiment.

### DETAILED DESCRIPTION OF THE EMBODIMENTS

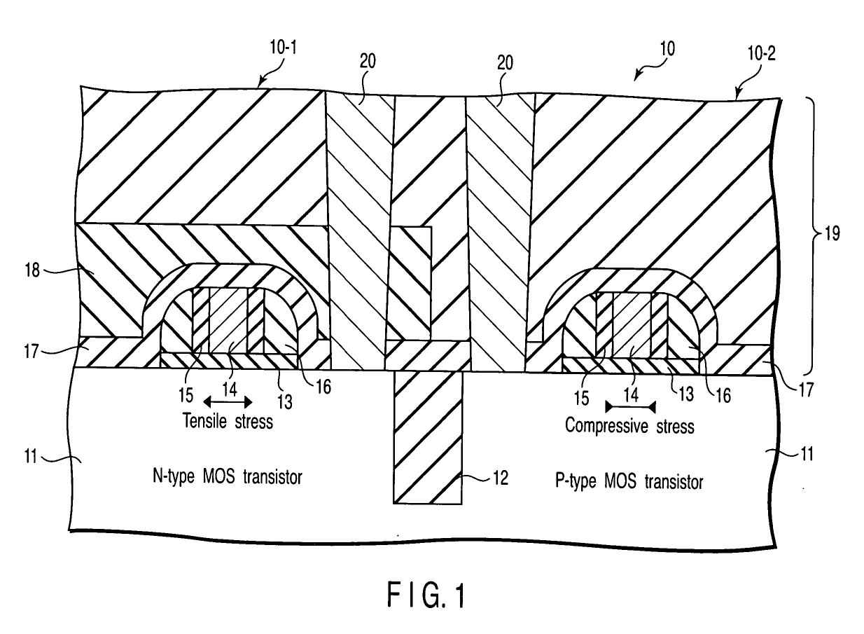

FIG. 1 shows a gate structure 10 of a CMOS transistor according to a first embodiment. Gate structures 10-1, 10-2 of N-type and P-type MOS transistors are isolated by an STI (Shallow Trench Isolation) 12 formed in a semiconductor substrate 11. Each gate structure includes a gate electrode 14 formed on the substrate or well region through a gate insulating film 13, a side wall insulating film 16 of an SiN film formed on the side wall of the gate electrode 14 through an insulating film 15 such as silicon oxide film, and a barrier SiN film 17 formed to cover the gate electrode 14 and the side wall insulating film 16.

In the gate structure 10, a PSZ (polysilazane) film 18 which is an SOG (Spin On Glass)-series film is formed to cover only the barrier SiN film 17 on the gate structure 10-1 of the N-type MOS transistor.

Since the PSZ film 18 has a good filling property and a strong contractile power, a tensile stress is applied to the N-type MOS transistor thereunder. The PSZ film 18 is used as a part of an inter-level insulating film (PMD) 19.

Further, an insulating film such as a silicon oxide film which does not usually apply any stress to the MOS transistors is deposited over the gate structures 10-1, 10-2 of the N-type and P-type MOS transistors and is planalized to provide the inter-level insulating film 19. Openings are formed in the inter-level insulating film 19 and contacts 20 are connected to semiconductor regions (not shown) such as source and drain regions of the MOS transistors via the openings.

According to the gate structure, a compressive stress is applied to the N-type MOS transistor by the barrier SiN film 17. However, such a stress is compensated by a large tensile stress caused by the PSZ film 18 which covers the barrier SiN film. As a result, the tensile stress or weak compressive stress is applied to the N-type MOS transistor, whereby the performance thereof is not adversely affected by the stress. On the other hand, the compressive stress is applied to the P-type MOS transistor and this is suitable for the performance thereof. In the following explanation for the embodiments, portions which are the same as those of FIG. 1 are denoted by the same reference numerals.

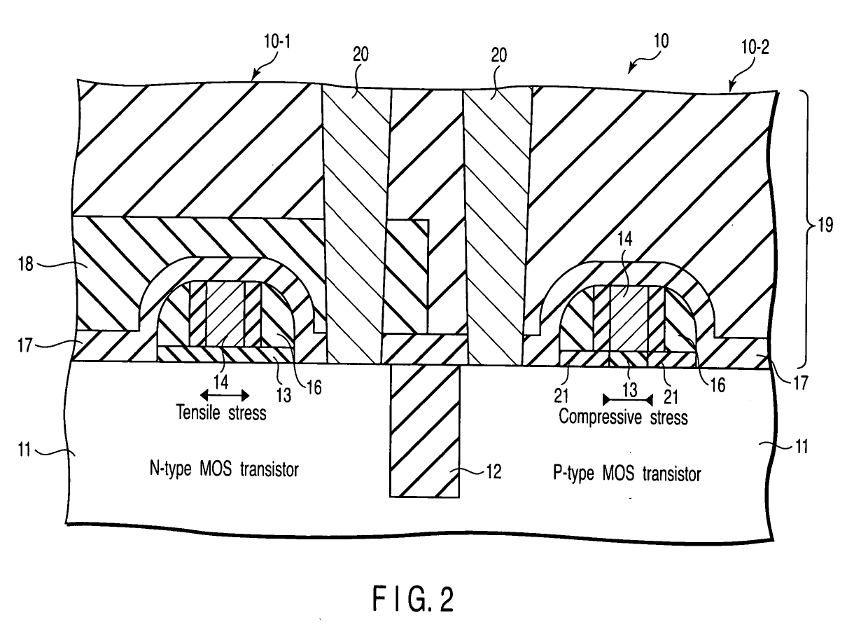

FIG. 2 shows a gate structure 10 of CMOS transistors according to a second embodiment. In the gate structure, a gate structure 10-1 of the N-type MOS transistor is the same as that of the first embodiment and the PSZ (polysilazane) film of the SOG-series film whose volume is contractible is used as the side wall insulating film 16 of the P-type MOS transistor.

That is, the barrier SiN film 17 applies the compressive stress to the P-type MOS transistor, but the compressive stress applied to the P-type MOS transistor from the barrier SiN film 17 can be enhanced since the internal PSZ film 16 contracts.

In this case, if TEOS film which is formed of an SiO₂-series material is provided as a stress relaxing film 21 under the PSZ film 16, the underlying TEOS film relaxes the stress of the PSZ film 16, and therefore, the stress by the PSZ film 16 itself can be prevented from being transmitted to the P-type MOS transistor.

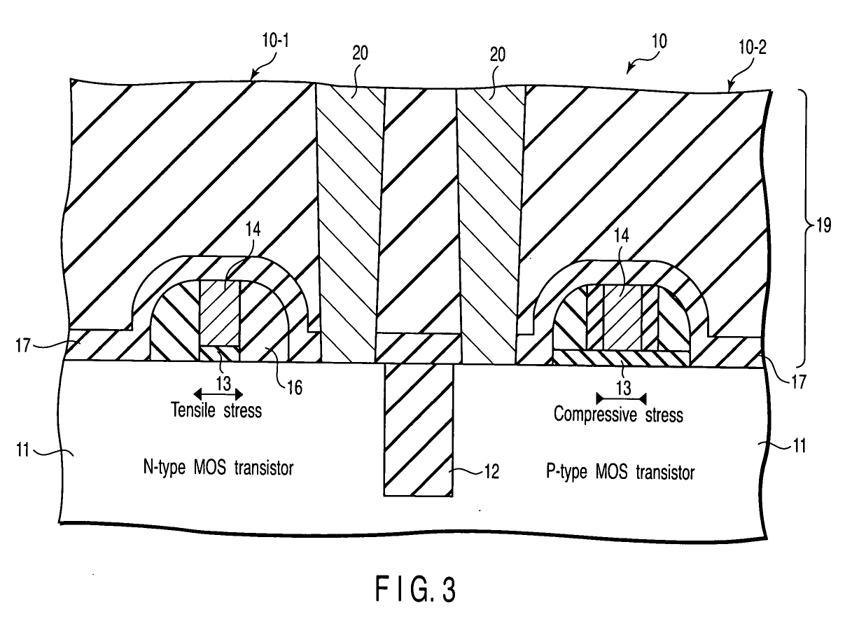

FIG. 3 shows a gate structure 10 of CMOS transistors according to a third embodiment. The gate structure is basically the same as that of FIG. 2, and an N-type MOS transistor without the underlying stress relaxing film 21 is provided.

That is, the PSZ (polysilazane) film of the SOG-series film whose volume is contractible is used as the side wall insulating film 16 of the N-type MOS transistor. Unlike the case of FIG. 2, since no TEOS film is provided, the tensile stress can be directly applied to the N-type MOS transistor from the PSZ film 16 used as the side wall insulating film. By applying the tensile stress, the characteristic of the N-type MOS transistor can be improved.

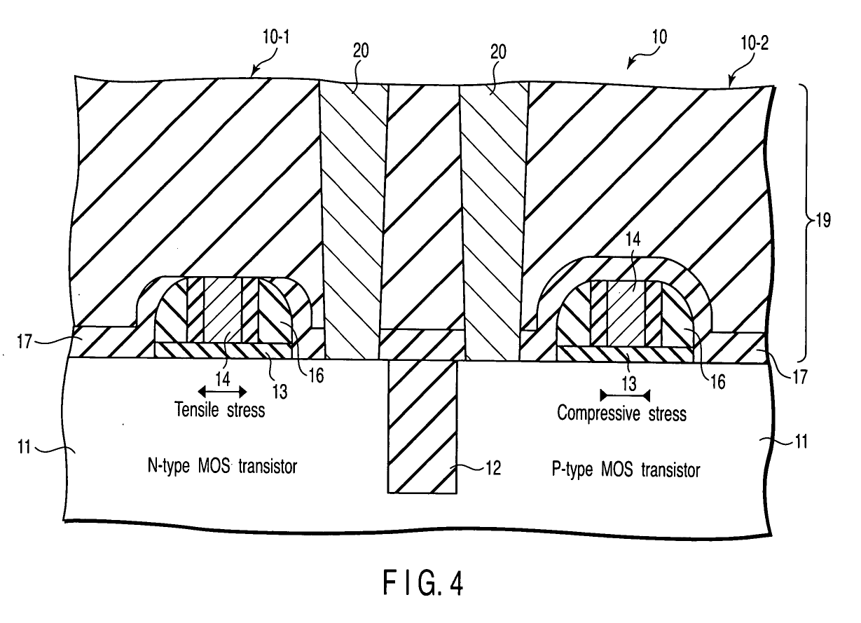

FIG. 4 shows a gate structure 10 of CMOS transistors according to a fourth embodiment. In the N-type gate structure 10-1, the N-type MOS transistor having a structure in which the barrier SiN film 17 is removed from the upper surface of the gate electrode 14 is provided.

Since the barrier SiN film 17 is removed, the compressive stress from the barrier SiN film 17 becomes weak. By reducing the stress applied to the N-type MOS transistor, the characteristic of the N-type MOS transistor can be improved.

As is clearly understood from the above embodiments, the stress from the structure other than the barrier SiN film of the MOS transistor and the stress applied from the barrier SiN film can be changed and the performance of at least one of the N-type and P-type MOS transistors can be enhanced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A MOS semiconductor device comprising:
a gate electrode provided via a gate insulating film,
a side wall insulating film formed on a side wall of the gate electrode with a protection insulating film disposed therebetween,
a barrier SiN film formed to cover the gate electrode and side wall insulating film, and
an inter-level insulating film formed to cover the barrier SiN film,
wherein an SOG-series high-stress material is used as part of the inter-level insulating film.

2. The MOS semiconductor device according to claim 1, wherein the high-stress material is a PSZ (polysilazane) film.

3. The MOS semiconductor device according to claim 2, wherein the inter-level insulating film is formed to further cover the PSZ film and includes an insulating film which applies no stress to the MOS transistor.

4. The MOS semiconductor device according to claim 3, wherein the insulating film which applies no stress to the MOS transistor is a silicon oxide film.

5. The MOS semiconductor device according to claim 1, wherein the side wall insulating film is formed on a stress alleviating film which is formed on the semiconductor substrate.

6. The MOS semiconductor device according to claim 5, wherein the stress alleviating film is formed of TEOS which is an SiO₂-series material.

7. The MOS semiconductor device according to claim 1, wherein a CMOS semiconductor device includes an N-type MOS transistor and a P-type MOS transistor.

8. The MOS semiconductor device according to claim 1, wherein the MOS semiconductor device according to claim 1 is an N-type MOS transistor.

9. A MOS semiconductor device comprising:
a gate electrode provided via a gate insulating film,
a side wall insulating film directly formed on a side wall of the gate electrode, and
a barrier SiN film formed to cover the gate electrode and side wall insulating film,
wherein a material whose volume contracts is used as the side wall insulating film.

10. The MOS semiconductor device according to claim 9, wherein the material whose volume contracts is an SOG-series material.

11. The MOS semiconductor device according to claim 9, wherein the MOS semiconductor device is an N-type MOS transistor.

12. A gate structure of a MOS semiconductor device comprising:
a semiconductor substrate, and
N-type and P-type MOS transistors formed on the semiconductor substrate and isolated by an STI region,
wherein each of the N-type and P-type MOS transistors includes a gate electrode provided via a gate insulating film, a side wall insulating film formed on a side wall of the gate electrode with a protection insulating film disposed therebetween, a barrier SiN film formed to cover the gate electrode and side wall insulating film, and an inter-level insulating film formed to cover the barrier SiN film and an SOG-series high-stress material is used as part of the inter-level insulating film in the N-type MOS transistor.

13. The gate structure of the MOS semiconductor device according to claim 12, wherein the high-stress material is a PSZ (polysilazane) film.

14. The gate structure of the MOS semiconductor device according to claim 12, wherein the inter-level insulating film is formed to further cover the PSZ film and includes an insulating film which applies no stress to the N-type MOS transistor.

15. The gate structure of the MOS semiconductor device according to claim 14, wherein the insulating film which applies no stress to the N-type MOS transistor is a silicon oxide film.

16. The gate structure of the MOS semiconductor device according to claim 12, wherein the side wall insulating film is formed on a stress alleviating film which is formed on the semiconductor substrate in the P-type MOS transistor.

17. The gate structure of the MOS semiconductor device according to claim 12, wherein the barrier SiN film which covers the gate electrode of the N-type MOS transistor is removed from the upper surface of the gate electrode.
